(19) United States
(12) Patent Application Publication
(10) Pub. No.: US 2002/0025684 A1
(43) Pub. Date: Feb. 28, 2002

(54) Gaseous process for surface preparation

(76) Inventors: Jeffrey W. Butterbaugh, Eden Prairie, MN (US); Brent D. Schwab, Burnsville, MN (US); Roger W. Gifford, Burnsville, MN (US)

Correspondence Address: VIDAS, ARRETT & STEINKRAUS, P.A., 6109 BLUE CIRCLE DRIVE, SUITE 2000, MINNETONKA, MN, 55343-9185, US

(21) Appl. No.: 09/828,056

(22) Filed: Apr. 6, 2001

Related U.S. Application Data
(60) Provisional application No. 60/195,873, filed on Apr. 7, 2000.

(51) Int. Cl. H01L 21/302; H01L 21/461

(52) U.S. Cl. 438/712

(57) ABSTRACT

Silicon oxide on a substrate may be etched by providing the substrate in a process chamber, evacuating the chamber to a pressure of less than about 1 torr; providing a gaseous mixture comprising an inert gas, alcohol and water to the process chamber and substrate and, subsequently further providing a gaseous anhydrous halogen containing species to the gaseous mixture provided to the process chamber and substrate.

### CROSS-REFERENCE TO RELATED APPLICATION

This application claims priority from U.S. provisional application No. 60/195,873, filed Apr. 7, 2000, the entire contents of which are incorporated herein by reference.

### BACKGROUND OF THE INVENTION

In the processing of semiconductor substrates for manufacturing semi-conductor integrated circuit chips and the like, it is often necessary to remove or etch silicon oxide films from the substrates.

A number of different techniques have been used to remove or etch silicon oxide films. These techniques generally fall in the category of wet techniques, plasma techniques or dry techniques.

In a wet etching process, the surface of a substrate is provided with a mask and immersed in a chemical solution comprising an acid which attacks the surface to be etched while leaving the mask otherwise intact. Alternatively, the acid may be sprayed onto the surface to be etched. Wet etching techniques, however, prove problematic where it is desired to achieve fine structures. Moreover, following the etching process, the substrate must be rinsed to remove residual etchant and other contaminants.

In plasma or reactive ion etching (RIE), a chamber is provided with a low pressure gas and a substrate, suitably masked. A voltage is applied to excite the gas and form various positive and negative ions, reactive neutral species and electrons. The various species interact with the surface of the substrate to etch the substrate. Plasma etching, however, is known to produce a roughened, damaged surface due to the overetching of underlayers.

A number of dry gas phase etching techniques have been developed to add to the arsenal of available etching techniques. To that end, the use of gaseous water, and nitrogen with anhydrous hydrogen fluoride to etch oxide from a substrate has been disclosed inter alia, in U.S. Pat. No. 4,749,440 (Blackwood, et al). The process is believed to work well at atmospheric pressure. Under vacuum conditions, however, control of the process, in particular, achieving consistent etch depth and uniformity, has proven to be difficult.

It has long been known that gas phase HF/water mixtures can be used to etch various silicon oxide films. Other references include J. P. Holmes, et al, “A Vapor Etching Technique for the Photolithography of Silicon Dioxide,” Microelectronics and Reliability, 5 pp 337-341 (1966); and K. Breyer, et al, “Etching of SiO₂ in Gaseous HF/H₂O,” IBM Technical Bulletin, 19(7) (December 1976), both of which used a HF/water azeotrope.

Another method for etching oxide from the surface of a substrate, using gaseous isopropyl alcohol (IPA) has been disclosed in U.S. Pat. No. B1 5,022,961 (Izumi, et al), U.S. Pat. No. 5,439,553 (Grant, et al) and U.S. Pat. No. 5,571,375 (Izumi, et al). In U.S. Pat. No. B1 5,022,961, the use of anhydrous HF and alcohol (such as IPA) for removing a native oxide film is disclosed. In U.S. Pat. No. 5,439,553, the use of a halide containing species such as anhydrous HF and a low molecular weight organic compound such as IPA at atmospheric pressure has been disclosed. In U.S. Pat. No. 5,571,375, IPA and anhydrous HF are used to selectively etch native oxide film relative to a BPSG film (boro-phospho silicate glass film) or a PSG film (phosphorus doped glass film).

Additional references directed to HF/alcohol mixtures may be found in U.S. Pat. No. 5,922,219 (Fayfield, et al).

Particularly good results have been achieved when using an HF/IPA process in combination with a ultraviolet (UV) chlorine pretreatment step as disclosed in WO 99/66545 entitled “Process For Achieving An Improved Surface Quality,” and U.S. Pat. No. 5,922,219.

All US patents and applications and all other published documents mentioned anywhere in this application are incorporated herein by reference in their entirety.

For the purpose of this disclosure, the term “comprising” and its cognates shall mean “including but not limited to”.

The invention in various of its embodiment is summarized below. Additional details of the invention and/or additional embodiments of the invention may be found in the Detailed Description of the Invention below.

### SUMMARY OF THE INVENTION

In one embodiment, the instant invention is directed to a method of etching silicon oxide. The method comprises the steps of providing a semiconductor substrate in a process chamber, the substrate comprising exposed silicon oxide, evacuating the chamber to a pressure of less than about 1 Torr, providing a gaseous mixture of at least one alcohol and water to the process chamber and, after subsequently, further providing a gaseous anhydrous halogen containing species to the gaseous mixture provided to the process chamber.

In another embodiment, the instant invention is directed to a method of etching a silicon oxide from the surface of the semiconductor substrate using a gaseous mixture of anhydrous HF, IPA, nitrogen and water. The method comprises the steps of providing a semiconductor substrate in a process chamber. The substrate comprises silicon oxide on the surface. The chamber is then evacuated to a pressure of less than about 1 torr and the substrate exposed to UV photons to heat the substrate to a temperature above ambient. A gaseous mixture of nitrogen, isopropyl alcohol and water is provided to the process chamber and, subsequently, hydrogen fluoride gas is provided to the process chamber along with the gaseous mixture of nitrogen, isopropyl alcohol and water.

The invention is directed in another embodiment to a method of etching silicon oxide comprising the steps of providing an in-process microelectronic device in a process chamber, the in-process microelectronic device comprising exposed silicon oxide, evacuating the chamber to a pressure of less than about 1 torr, providing a gaseous mixture of at least one alcohol and water to the process chamber and in-process microelectronic device and subsequently further providing a gaseous anhydrous halogen containing species to the gaseous mixture provided to the process chamber and in-process microelectronic device.

The instant invention is directed in another embodiment to a method of preparing a silicon surface prior to gate oxidation.

The instant invention is directed in another embodiment to a method of surface preparation for epitaxial silicon deposition.

In another embodiment, the instant invention is directed to a method of surface preparation before polysilicon deposition.

In another embodiment, the invention is directed to a method of surface preparation before silicide deposition.

In another embodiment, the invention is directed to a method of sacrificial oxide removal for micro-machining.

More generally, the instant invention may be used wherever it is necessary to prepare a surface and remove oxides using gaseous reactants.

### BRIEF DESCRIPTION OF THE FIGURES

FIG. 1 schematically depicts a top view of an embodiment of an apparatus suitable for carrying out the inventive process.

FIG. 2 schematically depicts the chamber of FIG. 1 from a side view.

FIG. 3 shows a schematic of a gas delivery system suitable for use in carrying out the inventive process.

FIG. 4 is a schematic side view of an alternative apparatus suitable for performing the inventive process.

FIG. 5 is a perspective cut-away view of the device of FIG. 4 showing insertion of a wafer substrate.

### DETAILED DESCRIPTION OF THE INVENTION

While this invention may be embodied in many different forms, there are described in detail herein specific preferred embodiments of the invention. This description is an exemplification of the principles of the invention and is not intended to limit the invention to the particular embodiments illustrated.

It has been unexpectedly discovered that by combining a gaseous mixture of anhydrous HF, IPA, nitrogen and water, an improved oxide etch may be achieved. The inventive method may be used to etch native oxides, chemical oxides, thermal oxides or deposited oxides whether doped or undoped.

In practice of the inventive method, a gas source is provided connected to a processing chamber containing the substrate material to be etched or cleaned. The processing chamber suitably comprises a vacuum vessel constructed of chemically inert material, which is hermetically sealed from the ambient atmosphere and can be evacuated below ambient pressure. The processing chamber is evacuated to a low base pressure, desirably, less than about 1 Torr. The substrate is desirably introduced into the processing chamber through an isolated load-lock chamber which can be pumped down to a similar base pressure. Introduction or removal of the substrate from the process chamber occurs through the load-lock chamber. Alternatively, the substrate may be introduced into the chamber before evacuation and the chamber evacuated to a pressure of less than about 1 Torr.

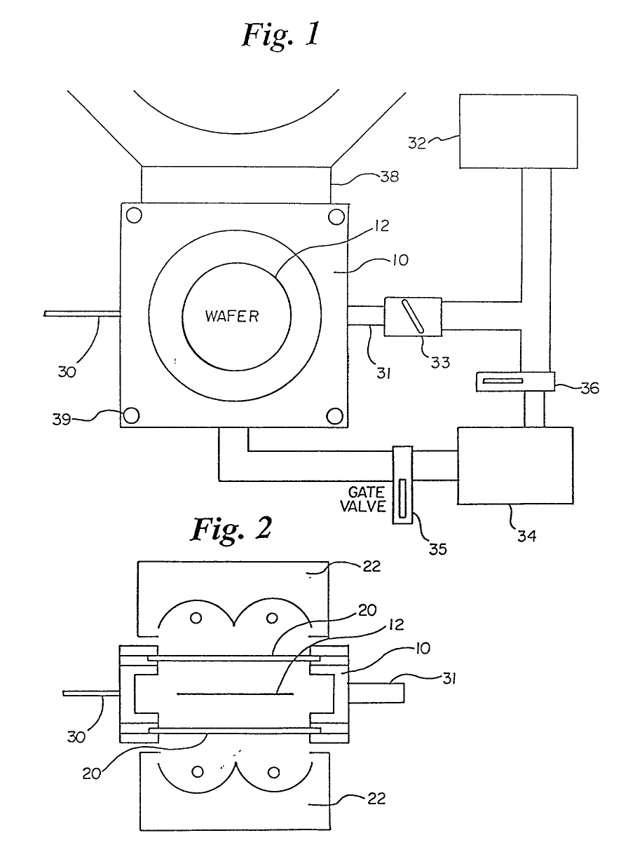

Referring to the figures, FIGS. 1 and 2 illustrate an apparatus suitable for carrying out the inventive process. Substrate 12 is located in reaction chamber 10. Reaction chamber 10 may be constructed of any combination of materials suitable for containing the gases described in this invention. An exemplary material from which the chamber may suitably be constructed is aluminum with a NEDOX® 615 coating, which is available from General Magnaplate of Racine, Wis. Windows 20 are optional, and should be transparent to any radiation which is desired in the chamber, such as the output of optional UV radiation source 22. Gas may enter the chamber through inlet port 30 and may leave the chamber through exhaust port 31. Gas may be delivered to inlet port 30 by any suitable delivery system. Vacuum pump 32 is connected to exhaust port 31 to allow the chamber to be evacuated. A throttle valve 33 is used to regulate the pressure in the chamber. Vacuum pump 32 should be able to maintain a vacuum level in the chamber of below 1 Torr, although more powerful pumps which can maintain higher vacuums may also be used. Rapid pumpdown may be provided by optional turbo pump 34 which may be isolated from the chamber and exhaust port by gate valves 35, 36. Wafer port 38 allows for transfer of wafers into and out of the chamber. This transfer may be manual or may be controlled by a robot. Heater cartridges 39 allow modification of the chamber temperature. Inside the chamber, the wafer rests on a wafer support (not shown). The wafer support may be composed of three pins which narrow to points at the top to minimize the area of contact with the wafer. Optionally, these pins may be connected together to form a single piece. Preferably, the pins are positioned to make contact at the edge of the wafer. The pins may be made of sapphire or any other material which is stable at the temperatures used to process the wafer and is resistant to the chemistries used to process the wafer. An alternate wafer support may be a pedestal which the wafer rests on.

The apparatus may optionally be clustered with other tools which operate at reduced pressures. This allows wafers to be transferred between tools without exposing the wafers to ambient air.

The windows 20, if provided, may be made of sapphire to allow UV radiation from a UV source 22 to impinge on substrate 12 in chamber 10. As discussed below, UV radiation provides a suitable method for increasing the temperature of the wafer. Substrate heating may alternatively be provided by an IR radiation source. In yet another alternative, heating of the substrate may be provided by a heater plate which the substrate rests on during processing, in which case windows 20 and UV radiation source 22 are unnecessary.

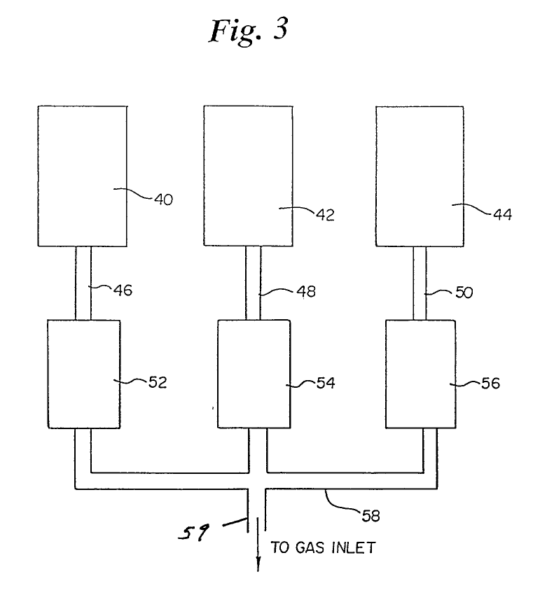

A schematic of a suitable gas delivery system is shown in FIG. 3. HF gas source 40 is connected to mass flow controller (MFC) 52 by line 46. Similarly, catalyst source 42 is connected to MFC 54 by line 48 and N₂ source 44 is connected to MFC 56 by line 50. Suitably, HF gas source 40 is heated to a temperature of 35° C., line 46 is heated to 40° C. and MFC 52 is heated to 50° C. Catalyst source 42 may suitably be heated to 60° C., line 48 heated to 85° C. and MFC 54 heated to 85° C. N₂ source 44, MFC 56 and pipe 50 may be at any temperature convenient for processing.

By providing an anhydrous HF source which is separate from the catalyst, the relative quantities of HF and catalyst (alcohol and water) in the treatment gas may be independently controlled. Also, the invention contemplates independently controlling the relative quantities of water and alcohol as well as independently controlling the relative quantities of anhydrous HF, water and alcohol.

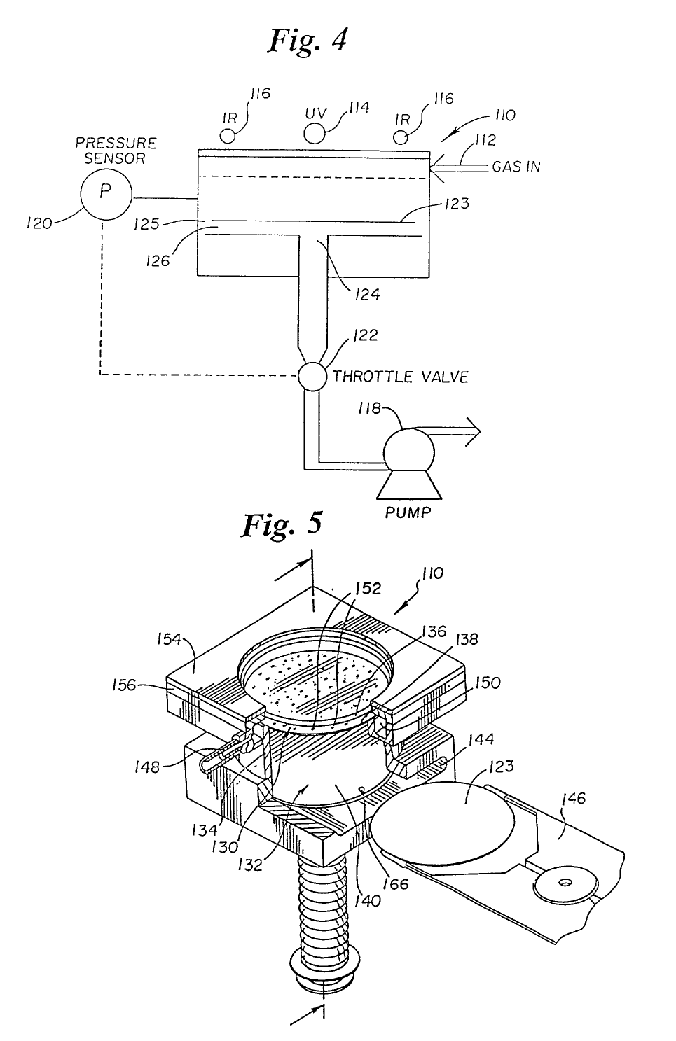

The output of the MFC's is mixed in manifold 58. Manifold 58 is maintained at a temperature of 45° C. Manifold 58 is connected with inlet port 30 (FIG. 1 or 2) or inlet port 112 (FIG. 4) via line 59. Line 59 is also maintained at a temperature of 45° C. Suitably the pipe and manifold system is teflon or teflon lined where corrosive chemicals contact it.

A suitable apparatus for preparing the gaseous combination of IPA, water and nitrogen is further disclosed in U.S. Pat. No. 6,065,481 B1 (Fayfield, et al). That apparatus may be modified for use in the present invention.

FIGS. 4 and 5 illustrate an alternative chamber suitable for carrying out the invention. This chamber is described in detail in U.S. Pat. No. 5,580,421 (C. Fred Hiatt, et al), incorporated herein by reference. FIG. 4 is a schematic diagram of the major component parts of the system. The reaction chamber is indicated generally at 110. The gas supply inlet is shown at 112 and is connected to the chamber 110. An optional ultraviolet lamp is shown at 114. Optional infrared lamps are shown at 116 which can be used to heat the substrate. A vacuum pump 118 is connected to the chamber 110. The total pressure in the chamber is measured by pressure sensor 120. Pressure sensor 120 controls the action of throttle valve 122 to allow for constant pressure processing in the chamber. In operation, the gas is fed into a first region of the chamber 110 (shown above the dotted line of FIG. 4). The gas uniformly flows from the first region to a second region, shown under the dotted line of FIG. 4 and located in reaction chamber 110, toward the surface of the wafer 123. The pressure drop between the inlet and the circular exhaust outlet 124 is small and a viscous flow regime is established in both the first and second regions. A peripheral gap 125 is defined between the edge of wafer 123 and the wall of chamber 110. A pumpout gap 126 is defined between the wafer 123 and the exhaust outlet 124, which is centrally located beneath the wafer 123. The peripheral gap 125, the pumpout gap 126, the centrally located circular exhaust outlet 124 and the pressure bias set at the exhaust outlet 124 create a uniform radial circumferential gas flow which causes the gas, after it has reacted with the wafer surface, to flow radially outward to the wafer edge, then through the peripheral gap 125, under the surface of the wafer and out the exhaust outlet 124.

FIG. 5 is a more detailed view of the chamber 110. The chamber 110 is a hermetically sealed chamber, constructed from aluminum and coated by a hardcoat anodization process, and is divided into two regions, a higher pressure gas inlet region, shown generally at 130, and a lower pressure reaction region, shown generally at 132. The gas inlet region 130 (first region discussed above in connection with FIG. 4) is defined by the chamber wall 134, a solid plate 136, and an optional perforated plate 138, each made of a material which is transparent to light of a selected range of wavelengths and inert so it does not react with the gas. In an embodiment the plates 136 and 138 are made of sapphire, which is transparent to both UV and IR wavelengths of light and is inert toward the gases used for treating the substrate. Plates 136 and 138 are transparent to UV and IR light, allowing the light from the UV lamps 114 and the IR lamp(s) 116 to penetrate to the surface of the substrate 123.

The reaction region 132 (second region discussed above in connection with FIG. 4) is defined by the chamber wall 134, the perforated plate 138 and a baffle plate 140 which slides vertically within the reaction region to define a load position and a processing position. The semiconductor substrate 123 is loaded into the chamber 110 through slot 144 using loading arm 146. When wafer 123 is loaded into the chamber, it is supported on pins 166 so that it defines a pumpout gap 126 (as shown in FIG. 4) between wafer 123 and baffle plate 140. In this particular apparatus gap 126 is about 8 mm. A gate valve (not shown) is used to seal the slot 144 during processing.

Gas flows are supplied through gas manifold 148 to annular channel 150, which opens into the gas inlet region 130. Gas is introduced into the annular channel 150 surrounding the chamber and then flows through the gap between the solid sapphire plate 136 and the perforated sapphire plate 138 and then through the perforations 152 in the perforated sapphire plate into the reaction region 132 between the perforated sapphire plate 138 and the baffle plate 140. The annular channel 150 is designed so that its flow conductance is larger compared to the flow conductance of the gap between the solid sapphire plate 136 and the perforated sapphire plate 138 so that the pressure in the annular channel 150 is approximately equal around the entire circumference even though the gas flows are introduced to the channel through a single small diameter tube 148. The isobaric nature of the annular ring 150 provides circumferential uniform flow of the gas from the edge to the center of the perforated plate 138. Further, the size and plurality of the perforations 152 in the perforated sapphire plate 138 are designed so that the flow conductance of the perforations 152 is much less than the flow conductance of the gap between the solid sapphire plate 136 and the perforated sapphire plate 138 so that the flow of gas through each perforation 152 is approximately equal. Top clamp 154 is used to hold solid sapphire plate 136 in place. Channel cover 156 together with chamber wall 134 defines the annular channel gap through which the gas flows enter into the gas inlet region 130.

The temperature of the wafer may be controlled by any suitable method. In one embodiment the wafer rests on a heater plate in the chamber. In another embodiment infra-red lamps provide a heat source for controlling the wafer temperature. In another embodiment the temperature of the wafer is raised to the desired processing temperature by ultraviolet (UV) radiation, as disclosed in U.S. Pat. No. 6,165,273 B1 (Fayfield, et al), incorporated herein by reference. Silicon and other semiconductor materials efficiently absorb UV light, in contrast to the metals typically used for construction of processing chambers. As a result, semiconductor substrates may be heated using UV radiation while minimizing heating in the surrounding processing chamber.

In the preferred apparatus, the UV lamp is located outside of the chamber. In this embodiment the chamber contains at least one window which allows transmission of UV light from the UV source to the substrate.

A suitable UV lamp is a 9 inch/7 millimeter bore linear, xenon-filled quartz flashlamp (made by Xenon corporation of Woburn, Mass.). A lamphouse suitable for use in the invention is provided with two such lamps and is supplied with 1500 Watts to power the lamps. Other sources of radiation, such as mercury lamps, may also be used as long as the source produces sufficient power in the wavelength range 100 to 1000 nanometers and the output photons react with the particular chemical system of interest. A more, or less, powerful UV source may be used. Of course, the power of the lamp will determine how quickly the substrate may be heated. With two 1500 Watt lamphouses, one on the front side and one on the back side, the temperature of a 150 mm silicon wafer may be increased from room temperature to 200° C. in approximately 30 seconds. The flashlamp power supply comprises a power supply capable of delivering an input power of up to 1500 Watts to the lamphouse with a fixed input pulse. The lamphouse may simply be a device for mounting the UV source or it may also comprise one or more parabolic or elliptical reflectors.

The UV controller may be any circuitry which when connected to the UV source can allow the UV source to deliver a desired amount of time averaged power. One method for controlling the time averaged power is through the use of a variable power supply. The Xenon RC 740 from Xenon corporation is an example of such a power supply which allows control over the number of pulses per second delivered by the lamphouse and the voltage of the discharge capacitor. Alternatively, the UV may be controlled manually by an operator.

The UV source may be run in an open loop without any temperature feedback during the heating step. If the UV source is a flashlamp, this allows pulse energy calibration thereby allowing for repeatable temperature control of the substrate in an open loop system. The chamber temperature may be controlled by a feedback mechanism associated with a feedback loop and resistive heater so as to maintain the chamber at a desired temperature. In the preferred embodiment, the chamber is held at 50° C., which maintains the wafer at the preferred processing temperature of about 45° C. The set point for the chamber needed to maintain the wafer at 45° C. will vary depending on the size and configuration of the chamber.

Although 45° C. is the preferred processing temperature, other temperatures may be suitable depending on the application. Lowering the temperature will increase the etch rate, leading to decreased processing time. However, lower temperatures can lead to instability in the etch rate. Similarly, higher processing temperatures will have better etch rate stability but will require longer processing times due to slower oxide removal rates. Temperatures between about 40 and 50° C. generally provide an appropriate balance of these factors.

An example of a suitable process chamber is the FSI Orion® Dry Cleaning Module (FSI International, Chaska, Minn.).

In the practice of the inventive method, chlorine gas may optionally be introduced into the process chamber during the initial UV heating step to remove surface contaminants and improve the oxide etchings results as disclosed in U.S. Pat. No. 5,922,219 (Fayfield, et al). The chamber is then evacuated.

Once the optional chlorine gas has been evacuated, a gaseous mixture of isopropyl alcohol (IPA) and water may then be provided to the process chamber typically for several seconds to deliver catalyst to the substrate prior to delivery of the HF. Desirably, the gaseous mixture further comprises nitrogen or another inert gas. The presence of an inert carrier gas is believed to minimize or prevent condensation and provide mass transport for low flow gases. Desirably, the water and IPA will be provided at a ratio that is azeotropic at its liquid boiling point. Other ratios of water and IPA may also be used. For example, a ratio of water and IPA which is azeotropic at the temperature of the vaporizer corresponding to a ratio of IPA:water of 88:12 by weight may be used. More generally, the gaseous mixture may be provided with IPA and water present within the range of about 83:17 to about 93:7 by weight.

Desirably, an inert carrier gas such as nitrogen and the combination of water and isopropyl alcohol will be provided in a ratio of about 5-50:1 (nitrogen: water and isopropyl alcohol) and more desirably 10-30:1. Ratios of 500:40 and 1000:40 have been observed to work well.

After a predetermined period of time, anhydrous hydrogen fluoride gas is added to the gaseous mixture and the pressure of the chamber allowed to rise to about 100 Torr. The gaseous mixture including the anhydrous hydrogen fluoride gas is delivered until the desired amount of silicon oxide is etched from the surface. After the desired amount of silicon oxide has been etched, the flow of all gasses is stopped and the chamber pumped to remove all gasses from the chamber. Desirably, the process gas is added in a flowing system so as to allow for prompt removal of any reaction products. Total gas flow rates of 10 sccm to about 5000 sccm may be beneficially employed. Desirably, the HF, the nitrogen and the IPA and water in combination will be provided on a volume basis ratio of 20-30:20-30:1 and more desirably, on a volume basis ratio of 25:25:1.

The gaseous flow may be provided in an axisymmetric pattern over the wafer surface. The gaseous flow may also be provided using reactive gas flow patterns which are nonsymmetric.

Following the oxide etch step, the substrate may optionally be subjected to additional treatment steps such as a UV chlorine and/or UV oxygen treatment. To that end, the process chamber may also share a transfer interface with a vacuum cluster robotic transfer unit which allows sequential transfer of substrate materials to or from other process modules without exposure to ambient atmosphere. Chamber apparatus designs suitable for the pretreatment process are the reaction chamber designs described in WO 96/19825 and U.S. Pat. No. 5,580,421 (C. Fred Hiatt, et al).

The process may also be carried out using other inert gases in place of or in addition to nitrogen. Suitable gases include the noble gases including He, Kr, Ar, Ne, and Xe and combinations thereof.

Additional modifications to the inventive process which are within the scope of the instant invention include the use of other alcohols in place of or in combination with IPA. Other alcohols which may be used include methanol, ethanol, and combinations thereof.

The inventive method may be carried out on any substrate having silicon oxide thereon. Suitable substrates include those made of silicon or gallium arsenide. More generally semiconductor substrates and other substrates for use in electronic applications may be used.

The inventive method as described above may be used to prepare a silicon surface prior to gate oxidation. Other uses for the inventive method include preparing a surface for epitaxial silicon deposition, polysilicon deposition and silicide deposition. The method may also be used for sacrificial oxide removal for micro-machining. More generally, the instant invention may be used wherever it is necessary to prepare a surface and remove oxides using gaseous reactants.

### EXAMPLES

In all of the inventive examples below, 200 mm prime silicon wafers with a 2000 A thermal oxide film were placed in the process chamber of an FSI Orion® Dry Cleaning Module (FSI International, Chaska, Minn.). The chamber was then sealed and evacuated to a pressure of less approximately 50 mTorr. Cl₂ was flowed into the process chamber at a flow rate of 400 sccm for 15 seconds with a pressure setpoint of 10 Torr. While flowing Cl₂ the temperature of the substrate was increased to 45° C. by exposing the substrate to UV photons from the topside UV flashlamp. The UV source was a broadband 2000 watt xenon flashlamp. The temperature of the process chamber was held at 45° C. The chamber was then pumped for approximately 10 seconds to a pressure of about 100 mTorr to remove the chlorine from the chamber. A gaseous mixture of nitrogen—provided at a flow rate of 1000 sccm (standard cubic centimeters per minute) and catalyst—provided at 40 sccm was then flowed into the process chamber for approximately 5 seconds to deliver catalyst to the substrate. During this time, the pressure of the chamber rose to approximately 3 Torr. Anhydrous HF gas at a flow rate of 1000 sccm was then added to the gaseous mixture and the substrate exposed to the gaseous mixture including the HF for a predetermined period of time. The chamber was then pumped for approximately 10 seconds to a pressure of about 200 mtorr. Nitrogen was then flowed into the chamber at 2000 sccm for 5 seconds with throttle valve open to a pressure of approximately 1.5 Torr and the chamber subsequently pumped to a pressure of about 90 mTorr. The nitrogen purge step was repeated once. Etch delta and etch uniformity were measured using a Rudolph Focus FE-VII ellipsometer.

In the experiments listed below, the ratio of H₂O to IPA in the was varied, as was the etch time.

The etch depth of each wafer was measured at 49 points and averaged over the wafer to arrive at an average etch depth for a given wafer. The standard deviation of the etch depth was also calculated for each wafer. The average etch depth for a given wafer was then averaged over all of the wafers to arrive at an Average Etch Depth.

TABLE I
Summary of Etch Delta and Etch Uniformity Measurements

| | | | | Avg. Std. | |
|---|---|---|---|---|---|
| | | | | Dev. (Å)^{‡} | |
| | | | | [Std Dev. | |
| | | Etch | Avg. Etch^{†} | of Avg. | |
| | | Time | Depth (Å) | Std. | No. of |
| Experiment | Catalyst* | (sec.) | [Std Dev.]^{††} | Dev.]^{‡‡} | wafers |
| 1 | 12% H₂O | 36 | 239.98 | 2.95 | 12 |
| (Inventive) | 88% IPA | | [9.73] | [0.26] | |
| 2 | 100% IPA | 36 | 179.27 | 4.34 | 23 |
| (Comparative) | | | [10.83] | [1.27] | |
| 3 | 12% H₂O | 20 | 34.59 [3.62] | 0.94 | 6 |
| (Inventive) | 88% IPA | | | [0.08] | |
| 4 | 100% IPA | 20 | 32.14 [2.54] | 1.51 | 3 |
| (Comparative) | | | | [0.33] | |

*Percentages given by weight
^{†}Average Etch defined as a 49 point measure over each wafer, averaged over all wafers
^{††}Denotes the standard deviation of the average etch depth of all of the wafers
^{‡}Denotes the average standard deviation of etch depth per wafer
^{‡‡}Denotes the standard deviation of the average standard deviation

As shown in the data above, the inventive process results in an increased etch rate as manifested by the increased etch depth as well as in an improved etch uniformity. This is a very surprising result since earlier work with HF and water but without alcohol under similar vacuum conditions gave very poor etch uniformity.

In addition to being directed to the embodiments described above and claimed below, the present invention is further directed to embodiments having different combinations of the dependent features described above and claimed below.

The above disclosure and Examples are intended to be illustrative and not exhaustive. The description and Examples will suggest many variations and alternatives to one of ordinary skill in this art. All these alternatives and variations are intended to be included within the scope of the attached claims. Those familiar with the art may recognize other equivalents to the specific embodiments described herein which equivalents are also intended to be encompassed by the claims attached hereto.

What is claimed is:

1. A method of etching silicon oxide comprising the steps of:
providing a substrate in a process chamber, the substrate comprising exposed silicon oxide;
evacuating the chamber to a pressure of less than about 1 torr;
providing a gaseous mixture of at least one alcohol and water to the process chamber and substrate; and
subsequently further providing a gaseous anhydrous halogen containing species to the gaseous mixture provided to the process chamber and substrate.

2. The method of claim 1 wherein the gaseous mixture further comprises an inert gas.

3. The method of claim 2 wherein the inert gas is selected from the group consisting of nitrogen, Ar, Kr, Xe and combinations thereof.

4. The method of claim 3 wherein the inert gas is nitrogen gas.

5. The method of claim 1 wherein the alcohol is IPA.

6. The method of claim 1 wherein the halogen containing species is HF.

7. The method of claim 2 wherein the inert gas is nitrogen, the alcohol is IPA and the halogen containing species is HF.

8. The method of claim 7 wherein the IPA and water are provided in a ratio of from 83:17 to 93:7 by weight.

9. The method of claim 8 wherein the IPA and water are provided in a ratio of 88:12 by weight.

10. The method of claim 8 wherein the HF, the nitrogen and the IPA and water in combination are provided on a volume basis ratio of 20-30:20-30:1

11. The method of claim 1 further comprising the step of exposing the substrate to UV photons to heat the substrate to a temperature above ambient prior to providing the gaseous mixture to the substrate.

12. The method of claim 1 wherein the silicon oxide is located on semiconductor substrate.

13. A method of etching silicon oxide from a semiconductor substrate comprising the steps of:
providing a semiconductor substrate in a process chamber, the semiconductor substrate comprising exposed silicon oxide;
evacuating the chamber to a pressure of less than about 1 torr;
providing a gaseous mixture of nitrogen, IPA and water to the process chamber and semiconductor substrate; and
subsequently further providing gaseous anhydrous HF to the gaseous mixture provided to the process chamber and semiconductor substrate.

14. The method of claim 13 wherein the IPA and water are provided in a ratio of from 83:17 to 93:7 by weight.

15. The method of claim 14 wherein the IPA and water are provided in a ratio of 88:12 by weight.

16. The method of claim 13 wherein the HF, the nitrogen and the IPA and water in combination are provided on a volume basis ratio of 20-30:20-30:1.

17. A method of etching silicon oxide comprising the steps of:
providing an in-process microelectronic device in a process chamber, the in-process microelectronic device comprising exposed silicon oxide;
evacuating the chamber to a pressure of less than about 1 torr;
providing a gaseous mixture of at least one alcohol and water to the process chamber and in-process microelectronic device; and
subsequently further providing a gaseous anhydrous halogen containing species to the gaseous mixture provided to the process chamber and in-process microelectronic device.
